(19) United States
(12) Patent Application Publication
(10) Pub. No.: US 2013/0295712 A1
(43) Pub. Date: Nov. 7, 2013

(54) METHODS OF TEXTURING SURFACES FOR CONTROLLED REFLECTION

(71) Applicants: Tianniu CHEN, Rocky Hill, CT (US); Michael B. KORZENSKI, Danbury, CT (US); Ping JIANG, Danbury, CT (US); Lawrence H. DUBOIS, Danbury, CT (US)

(72) Inventors: Tianniu CHEN, Rocky Hill, CT (US); Michael B. KORZENSKI, Danbury, CT (US); Ping JIANG, Danbury, CT (US); Lawrence H. DUBOIS, Danbury, CT (US)

(73) Assignee: ADVANCED TECHNOLOGY MATERIALS, INC., Danbury, CT (US)

(21) Appl. No.: 13/463,448

(22) Filed: May 3, 2012

(51) Int. Cl. H01L 31/18

(52) U.S. Cl. 438/71; 257/E31.127

(57) ABSTRACT

Novel methods for the texturing of photovoltaic cells is described, wherein texturing minimizes reflectance losses and hence increases solar cell efficiency. In one aspect, a microstamp with the mirror inverse of the optimum surface structure is described. The photovoltaic cell substrate to be etched and the microstamp are immersed in a bath and pressed together to yield the optimum surface structure. In another aspect, micro and nanoscale structures are introduced to the surface of a photovoltaic cell by wet etching and depositing nanoparticles or introducing metal induced pitting to a substrate surface. In still another aspect, remote plasma source (RPS) or reactive ion etching (RIE), is used to etch nanoscale features into a silicon-containing substrate.

### CROSS-REFERENCE TO RELATED APPLICATIONS

This application is filed under the provisions of 35 U.S.C. §111(a) and claims priority of International Patent Application No. PCT/US10/55418 filed on 4 Nov. 2010 entitled “Methods of Texturing Surfaces for Controlled Reflection” in the name of Tianniu CHEN et al., which claims priority to U.S. Provisional Patent Application No. 61/258,449 filed on 5 Nov. 2009 and U.S. Provisional Patent Application No. 61/313,473 filed on 12 Mar. 2010, all of which are hereby incorporated herein by reference in their entireties.

### FIELD

The present invention relates generally to methods of texturing surfaces, more particularly to texturing surfaces to decrease the reflectance and hence increase the efficiency of photovoltaic cells.

### DESCRIPTION OF THE RELATED ART

Optoelectronic devices rely on the optical and electronic properties of materials to either produce or detect electromagnetic radiation or to generate electricity from ambient electromagnetic radiation. Photosensitive optoelectronic devices convert electromagnetic radiation into electricity. Solar cells, also known as photovoltaic (PV) devices, are used to generate electrical power from ambient light. PV devices are used to drive power consuming loads to provide, for example, lighting, heating, or to operate electronic equipment such as computers or remote monitoring or communications equipment. These power generation applications often involve the charging of batteries or other energy storage devices so that equipment operation may continue when direct illumination from the sun or other ambient light sources is not available.

Solar cells are characterized by the efficiency with which they can convert incident solar power to useful electric power. Devices utilizing crystalline silicon dominate commercial applications, and some have achieved efficiencies of 23% or greater. However, efficient single crystal silicon-based devices, especially of large surface area, are difficult and expensive to produce due to the problems inherent in producing large crystals without significant efficiency-degrading defects.

Control of light scattering in photovoltaic cells can increase performance dramatically. For example, single crystal silicon (s-Si) reflects approximately 35% of incident visible light. The surface is typically anisotropically textured using a mixture of a base (e.g., NaOH or KOH) and an alcohol (e.g., isopropanol) at greater than 60° C. for approximately 30 minutes. The resulting surface has a square pyramidal structure due to the etching rate difference between different crystal planes of silicon ((111)<<(110)<(100)). Light reflection over a broad spectral range is reduced to below 10% and thus the conversion efficiency increases typically 3 percentage points (absolute).

Polycrystalline (p-Si) or multicrystalline (mc-Si) silicon (either sliced from a boule, grown in a ribbon, or deposited on a substrate) is much more difficult to texture effectively since many crystal planes are exposed in a single cell and the texturing appears random. Typically, the substrate is etched in a mixture of HF and HNO₃ at temperature less than 50° C. While the surface can be made “black” (i.e., reflectivity less than a few percent) again via surface etching, the resulting surface is so rough that the surface recombination velocity (SRV) of electrons and holes becomes so high that the resulting cells have low conversion efficiency. These “black” surfaces may be chemically etched to remove some roughness and therefore improve the electrical properties, but this leads to increased reflectivity. Moreover, since each p-Si substrate has a different mix of exposed silicon planes, it is difficult to achieve reproducible high volume manufacturing. Accordingly, some p-Si photovoltaic cells are manufactured without any surface texturing.

An alternative to wet chemical processing is plasma processing based on reactive ion etching (RIE) which has the advantage of safer handling, less waste disposal, reduced use of deionized water and single sided etching. That said, plasma processes do entail additional cost and complexity due to the need for vacuum systems. Furthermore, common plasma etching gases such as CF₄, C₂F₆ and SF₆ have a global warming potential many thousands of times worse than CO₂ (Inventory of U.S. Greenhouse Gas Emissions and Sinks: 2002). Nevertheless, plasma processes allow for the texturing of multi-crystalline materials without saw damage, unlike wet chemical texture methods which require surface defects to create active texturing sites. In fact, plasma texturing yields photovoltaic cells with similar to slightly higher conversion efficiencies than that obtained using wet acidic isotropic texturing. Plasma processing is also particularly appropriate for wafers produced without surface damage such as Si ribbons and epitaxial layers on low-cost Si substrates, for which no easy wet chemical texturing processes are available. Disadvantageously, RIE relies on ion bombardment, which creates subsurface damage. The damaged region must be subsequently removed by employing a damage removal etch (DRE). As expected, the DRE increases the reflectivity of the surface, but is a necessary trade-off in voltaic device processing to minimize the surface recombination velocity.

### SUMMARY

In one aspect, a method for the controlled texturing of substrates is described, said method comprising immersing a microstamp and a substrate to be etched together in a bath and pressing the microstamp to the substrate.

In another aspect, a method of introducing a nanometer scale surface roughness to a substrate surface, said method comprising (i) depositing nanoparticles on the substrate surface; (ii) introducing metal induced pitting to a substrate surface; (iii) using remote plasma source (RPS) or reactive ion etching (RIE); or (iv) immersing a microstamp and a substrate to be etched together in a bath and pressing the microstamp to the substrate to etch nanometer scale features into the substrate surface.

In still another aspect, a method for the controlled texturing of substrates is described, wherein said method comprises masking a substrate to be etched with a microstamp and using gas phase etching to etch the substrate to introduce texture thereon.

In yet another aspect, an etchant composition comprising, consisting of, or consisting essentially of at least one alkaline component, at least one surfactant, at least one metal salt, and water is described, wherein the etchant composition is substantially devoid of any low boiling point alcohol components.

In another aspect, an etchant composition comprising, consisting of, or consisting essentially of at least one amine carboxylate, at least one surfactant, at least one metal salt, and water is described, wherein the etchant composition is substantially devoid of any low boiling point alcohol components.

In still another aspect, a method of introducing micron-scale surface roughness to semiconductor material, said method comprising contacting the semiconductor material with an etchant composition under conditions sufficient to rough the surface of the semiconductor material, wherein the etchant composition comprises at least one alkaline component, at least one surfactant, at least one metal salt, and water, wherein the etchant composition is substantially devoid of any low boiling point alcohol components.

Another aspect relates to a method of introducing a micrometer scale surface roughness to a substrate surface, said method comprising (i) using an etchant composition; or (ii) immersing a microstamp and a substrate to be etched together in a bath and pressing the microstamp to the substrate to etch micrometer scale features into the substrate surface.

Other aspects, features and advantages will be more fully apparent from the ensuing disclosure and appended claims.

### BRIEF DESCRIPTION OF THE DRAWINGS

FIG. 1 illustrates a schematic of the microstamping method described herein.

FIG. 2 illustrates semi-spherical scallops.

FIG. 3 illustrates a novel method of introducing secondary texturing to the surface of the photovoltaic cell substrate.

FIG. 4 is a schematic illustration of the process of metal induced pitting.

FIG. 5 illustrates the etch rate of silicon as a function of metal salt at 95° C.

FIG. 6 illustrates the etch rate of silicon as a function of metal salt at 80° C.

### DETAILED DESCRIPTION AND PREFERRED EMBODIMENTS THEREOF

The present invention relates generally to methods of texturing surfaces, more particularly to texturing surfaces to decrease the reflectance without substantially increasing the surface recombination velocity and hence increase the efficiency of photovoltaic cells.

“Substantially devoid” is defined herein as less than 2 wt. %, preferably less than 1 wt. %, more preferably less than 0.5 wt. %, and most preferably less than 0.1 wt. %. “Devoid” corresponds to 0 wt. %.

As used herein, “about” is intended to correspond to ±5% of the stated value.

As defined herein, a “photovoltaic device” comprises a photovoltaic cell including at least one semiconductor material.

Herein the term “semiconductor” denotes materials which can conduct electricity when charge carriers are induced by thermal or electromagnetic excitation. Traditionally, photosensitive optoelectronic devices have been constructed of a number of inorganic semiconductors, e.g., crystalline, polycrystalline and amorphous silicon, gallium arsenide, cadmium telluride, copper indium gallium selenide (CIGS), and others. The semiconductor material can be doped or undoped.

It should be appreciated that the term “single crystalline Si” or “single crystal Si” is synonymous with the term “monocrystalline Si.”

It should be appreciated that the term “polycrystalline Si” is synonymous with the term “multicrystalline Si.”

As defined herein, a “chalcogenide” corresponds to a molecule consisting of a chalcogen ion (e.g., sulfide, selenide, telluride) and an electropositive metal.

As used herein, a “noble metal” includes ruthenium, rhodium, palladium, silver, osmium, iridium, platinum and gold. All other metals for the purpose of the present disclosure are considered non-noble metals.

As used herein, “gas phase deposition” includes physical vapor deposition such as evaporation, sputter deposition, electron beam deposition, etc. and chemical vapor deposition, atomic layer deposition, and variations thereof.

In a first aspect, an etchant composition and a method of using same to introduce micron-scale surface roughness to semiconductor material is described. The etchant composition can comprise, consist of, or consist essentially of at least one surfactant, at least one metal salt, and water, wherein the etchant composition is substantially devoid of any low boiling point alcohol components. In one embodiment, the etchant composition can comprise, consist of, or consist essentially of at least one alkaline component, at least one surfactant, at least one metal salt, and water, wherein the etchant composition is substantially devoid of any low boiling point alcohol components. In another embodiment, the etchant composition can comprise, consist of, or consist essentially of at least one alkaline component, at least two surfactants, at least one metal salt, and water, wherein the etchant composition is substantially devoid of any low boiling point alcohol components. In still another embodiment, the etchant composition can comprise, consist of, or consist essentially of at least one amine carboxylate, at least one surfactant, at least one metal salt, and water, wherein the etchant composition is substantially devoid of any low boiling point alcohol components. As defined herein, “low boiling point alcohol components” correspond to straight-chained or branched C₁-C₆ alcohols having boiling points less than about 90° C. including, but not limited to, methanol, ethanol, isopropanol, and t-butyl alcohol. In another embodiment, the etchant composition is substantially devoid of straight-chained or branched C₁-C₆ alcohol (e.g., meth-, eth-, prop-, but-, pent-, hex-) components. Most preferably, the first composition is devoid of isopropanol.

Alkaline components contemplated include alkali hydroxides, carbonates, hydrogen carbonates and quaternary ammonium hydroxides such as NaOH, KOH, RbOH, CsOH, Na₂CO₃, NaHCO₃, K₂CO₃, KHCO₃, CsOH, and NR₄OH, wherein R can be the same as or different from one another and is selected from the group consisting of C₁-C₆ alkyls (e.g., methyl, ethyl, propyl, butyl, pentyl, hexyl), C₆-C₁₀ aryl (e.g., benzyl), and combinations thereof. Preferably, the at least one alkaline component comprises NaOH, KOH, RbOH, CsOH, or combinations thereof, even more preferably NaOH, KOH, or a combination of NaOH/KOH.

Amine carboxylates contemplated include amine gallates and amine salicylates, wherein the amine carboxylate is generated in situ or ex situ. Amine gallates are produced using a combination of components comprising, consisting of or consisting essentially of at least one alkanolamine, gallic acid, water, pyrazine, optionally at least one oxidant and optionally at least one surfactant. Amine salicylates are produced using a combination of components comprising, consisting of or consisting essentially of at least one alkanolamines, salicylic acid, water, pyrazine, optionally at least one oxidant and optionally at least one surfactant.

Metal salts contemplated include Group II (e.g., magnesium, calcium, strontium, barium), Group IV metals (e.g., silicon, germanium, tin, lead), copper, lanthanum, or any combination thereof, wherein the metal may be the cation or a atom of a polyatomic anion. For example, metal salts contemplated include, but are not limited to, Ca(OH)₂, Sr(OH)₂, Ba(OH)₂, CaO, SrO, BaO, Ca(CO₃)₂, Ca(NO₃)₂, Sr(NO₃)₂, Ba(NO₃)₂, CuSO₄.5H₂O, CaSO₄, SrSO₄, BaSO₄, Cu(OH)₂, Na₂(GeO₃), Na₂(SnO₃), Na₄(SiO₄), K₂(GeO₃), K₄(SiO₄), K₂(SnO₃), LaCl₃.7H₂O, La₂(SO₄)₃ and its hydrates, SnCl₄.5H₂O, and combinations thereof. Preferably, the metal salt comprises CaO, CaSO₄, BaO, CaOH or BaOH. Although not wishing to be bound by theory, it is thought that when the metal salt comprises CaO or BaO, it will undergo an in situ conversion to Ca(OH)₂ or Ba(OH)₂, respectively.

Surfactants contemplated include, but are not limited to, nonionic, anionic, cationic, and/or zwitterionic surfactants. For example, suitable non-ionic surfactants may include fluoroalkyl surfactants, ethoxylated fluorosurfactants, polyethylene glycols, polypropylene glycols, polyethylene or polypropylene glycol ethers, dodecylbenzenesulfonic acid thereof, polyacrylate polymers, dinonylphenyl polyoxyethylene, silicone or modified silicone polymers, acetylenic diols or modified acetylenic diols, and alkylphenol polyglycidol ether, sorbitan esters (e.g., sorbitan monolaurate, sorbitan monopalmitate, sorbitan monostearate, sorbitan tristearate, sorbitan monooleate (i.e., Span 80), sorbitan trioleate), polysorbate surfactants (e.g., polyoxyethylene (20) sorbitan monolaurate, polyoxyethylene (20) sorbitan monopalmitate, polyoxyethylene (20) sorbitan monostearate, polyoxyethylene (20) sorbitan monooleate, polyoxyethylene sorbitan trioleate, polyoxyethylene sorbitan tristearate), alkyl polyglucosides (e.g., TRITON™ BG-10) as well as combinations comprising at least one of the foregoing. Anionic surfactants contemplated in the compositions described herein include, but are not limited to, fluorosurfactants such as ZONYL® UR and ZONYL® FS-62 (DuPont Canada Inc., Mississauga, Ontario, Canada), sodium alkyl sulfates such as sodium ethylhexyl sulfate (NIAPROOF® 08), ammonium alkyl sulfates, alkyl (C₁₀-C₁₈) carboxylic acid ammonium salts, sodium sulfosuccinates and esters thereof, e.g., dioctyl sodium sulfosuccinate (DSS), alkyl (C₁₀-C₁₈) sulfonic acid sodium salts, and the di-anionic sulfonate surfactants DowFax™ (The Dow Chemical Company, Midland, Mich., USA) such as the alkyldiphenyloxide disulfonate DowFax™3B2. Cationic surfactants contemplated include alkylammonium salts such as cetyltrimethylammonium bromide (CTAB) and cetyltrimethylammonium hydrogen sulfate. Suitable zwitterionic surfactants include ammonium carboxylates, ammonium sulfates, amine oxides (e.g., Dimethyldodecylamine oxide (DMAO)), N-dodecyl-N,N-dimethylbetaine, betaine, sulfobetaine, alkylammoniopropyl sulfate, and the like. Alternatively, the surfactants may include water soluble polymers including, but not limited to, polyethylene glycol (PEG), polyethylene oxide (PEO), polypropylene glycol (PPG), polyvinyl pyrrolidone (PVP), cationic polymers, nonionic polymers, anionic polymers, hydroxyethylcellulose (HEC), acrylamide polymers, poly(acrylic acid), carboxymethylcellulose (CMC), sodium carboxymethylcellulose (Na CMC), hydroxypropylmethylcellulose, polyvinylpyrrolidone K30, BIOCARE™ polymers, DOW™ latex powders (DLP), ETHOCEL™ ethylcellulose polymers, KYTAMERT™ PC polymers, METHOCELT™ cellulose ethers, POLYOX™ water soluble resins, SoftCATT™ polymers, UCARE™ polymers, UCON™ fluids, PPG-PEG-PPG block copolymers, PEG-PPG-PEG block copolymers, and combinations thereof. The water soluble polymers may be short-chained or long-chained polymers and may be combined with the nonionic, anionic, cationic, and/or zwitterionic surfactants described herein. Preferably, the at least one surfactant includes DSS, TRITON™ BG-10, Span 80, DMAO, or combinations thereof. In a particularly preferred embodiment, two surfactants are used, e.g., DSS/Span 80 or DSS/TRITON™ BG-10.

Optionally, the surfactant may include materials that are generically referred to as defoamers including, but are not limited to, silicone-oil based, mineral-oil based, natural-oil based, acetylenic-based, and phosphoric acid ester-based agents. More preferably, the defoaming agents include, but are not limited to, ethylene oxide/propylene oxide block copolymers such as Pluronic® (BASF®) products (e.g., Pluronic®17R2, Pluronic®17R4, Pluronic®31R1 and Pluronic®25R2), alcohol alkoxylates such as Plurafac® products (BASF®) (e.g., Plurafac®PA20), fatty alcohol alkoxylates such as Surfonic® (Huntsmen) (e.g., Surfonic®P1), phosphoric acid ester blends with non-ionic emulsifiers such as Defoamer M (Ortho Chemicals Australia Pty. Ltd.), and Super Defoamer 225 (Varn Products), and combinations thereof.

The amounts of each component in the etchant composition of the first aspect comprising, consisting of, or consisting essentially of at least one alkaline component, at least one surfactant, at least one metal salt, and water, wherein the etchant composition is substantially devoid of any low boiling point alcohol components, based on the total weight of the composition, is:

| | | Preferred | Most |
|---|---|---|---|
| | Amount (wt %) | Amount (wt %) | preferred (wt %) |
| alkaline | about 1 to | about 5 to | about 9 to about |
| component(s) | about 20 wt % | about 15 wt % | 13 wt % |
| surfactant(s) | up to 5 wt % | about 0.01 to | about 0.025 to about |
| | | about 0.06 wt % | 0.05 wt % |
| metal salt(s) | up to 1 wt % | about 0.005 to | about 0.005 to about |
| | | about 0.5 wt % | 0.2 wt % |

The amounts of each component in the etchant composition of the first aspect comprising, consisting of, or consisting essentially of at least one amine carboxylate, at least one surfactant, at least one metal salt, and water, wherein the etchant composition is substantially devoid of any low boiling point alcohol components, based on the total weight of the composition, is:

| | Amount (wt %) | Preferred Amount (wt %) |
|---|---|---|
| amine | about 1 to about 20 wt % | about 5 to about 15 wt % |
| carboxylate(s) | | |
| surfactant(s) | up to 5 wt % | about 0.01 to about 0.05 wt % |
| metal salt(s) | up to 1 wt % | about 0.005 to about 0.5 wt % |

The compositions of the first aspect described herein have pH greater than about 12, more preferably greater than about 13. It is to be appreciated that the pH of the composition of the first aspect described herein may be greater than 14, depending on the components used and the amount thereof.

In addition to being devoid of isopropanol and other low boiling point alcohol components, the compositions of the first aspect are also preferably substantially devoid of abrasive materials such as silica, alumina, etc., and hydrogen peroxide and other oxidizing agents.

In a particularly preferred embodiment, the compositions of the first aspect comprise, consist of, or consist essentially of at least one alkaline component, at least two surfactants, at least one metal salt, and water, wherein the etchant composition is substantially devoid of any low boiling point alcohol components. Even more preferably, the composition of the first aspect comprises, consists of, or consists essentially of at least one alkaline component, dioctyl sodium sulfosuccinate, at least one additional surfactant, at least one metal salt, and water, wherein the etchant composition is substantially devoid of any low boiling point alcohol components, and wherein the at least one metal salt is selected from the group consisting of BaOH, CaO, Ca(OH)₂, CaSO₄, and combinations thereof.

In another embodiment, the aforementioned compositions of the first aspect further include semiconductor material, wherein the semiconductor material may comprise silicon, gallium arsenide, cadmium telluride, or copper indium gallium selenide (CIGS). For example, the composition of the first aspect may include at least one alkaline component, at least one surfactant, at least one metal salt, semiconductor material, and water, wherein the etchant composition is substantially devoid of any low boiling point alcohol components, wherein the semiconductor material comprises silicon, gallium arsenide, cadmium telluride, or copper indium gallium selenide (CIGS). Alternatively, the composition of the first aspect may include at least one amine carboxylate, at least one surfactant, at least one metal salt, semiconductor material, and water, wherein the etchant composition is substantially devoid of any low boiling point alcohol components, wherein the semiconductor material comprises silicon, gallium arsenide, cadmium telluride, or copper indium gallium selenide (CIGS). The semiconductor material may be dissolved and/or suspended in the etchant composition.

The method of using the etchant composition to introduce micron-scale surface roughness to semiconductor material comprises contacting the semiconductor material with the etchant composition under conditions sufficient to etch the surface of the semiconductor material. Preferably, the roughness introduced is micron-scale surface roughness, wherein the pyramids etched into the surface have a lateral measurement of about 2 to about 10 microns, with good coverage of the pyramids across the surface. As defined herein, “good coverage” corresponds to roughening of at least 90% of the surface of the semiconductor material, preferably at least 95%, and most preferably at least 99% of the surface of the semiconductor material is roughened. It should be appreciated by the skilled artisan that the pyramids etched in the surface of the substrate can be the same size or a different size relative to other pyramids on the surface. As defined herein, “pyramids” correspond to any pointy structure that is etched into the surface whether symmetrical or non-symmetrical and can be a square pyramid, a tetrahedral pyramid, a pentagonal pyramid, or any shape approximating that of a cone or a pyramid.

In removal applications, the etchant compositions of the first aspect can be applied in any suitable manner to the semiconductor substrate to be roughened, e.g., by spraying the etchant composition on the surface, by dipping (in a volume of the etchant composition) of the substrate, by contacting the substrate with another material, e.g., a pad, or fibrous sorbent applicator element, that is saturated with the etchant composition, by contacting the substrate with a circulating etchant composition, or by any other suitable means, manner or technique, by which the etchant composition is brought into contact with the semiconductor substrate to be roughened. Where necessary, the back surface of the substrate can be masked to avoid exposure to the etchant composition.

In use of the compositions of the first aspect for roughening semiconductor material, the compositions typically are contacted with the substrate for a time of from about 10 sec to about 120 minutes, at temperature in a range of from about 20° C. to about 200° C., preferably about 70° C. to about 100° C., even more preferably about 80° C. to about 90° C. Such contacting times and temperatures are illustrative, and any other suitable time and temperature conditions may be employed that are efficacious to roughen the semiconductor material.

Following the achievement of the desired roughening, the etchant composition may be removed from the device to which it has previously been applied by rinsing. Preferably, the rinse solution for the composition of the first aspect includes deionized water. Thereafter, the roughened semiconductor material may be dried using nitrogen or a spin-dry cycle.

In a second aspect, a novel method for the controlled texturing of semiconductor materials is described, wherein a microstamp with the optimum surface structure is manufactured. The microstamp may be a mirror inverse of the optimum surface structure, an anode with features to enhance etching in specific places, and/or a mask with features to ensure that certain parts of the surface are etched while others are not. The microstamp may be made out of a variety of materials including, but not limited to, metals, ceramics, glasses and plastics/polymers and may be made using any process such as micromachining, photolithography, embossing, etc. The semiconductor material substrate to be etched and the microstamp are immersed in a bath and pressed together. Holes may be added to the microstamp to ensure that the etching chemistry reaches the substrate surface and etch products are easily removed. Vibration and/or pulsing may also be used. The microstamp may be of any size, covering only a fraction of the substrate at any one time or large enough to cover multiple substrates. Advantageously, only the front surface of the substrate is textured without having to mask the back surface. In one embodiment, the stamp and the substrate may be alternately pressed and removed a number of times to ensure adequate fluid transfer. In another embodiment, the microstamp may be slightly flexible to minimize substrate breakage. In still another embodiment, a potential may be placed on the upper and lower surfaces to enhance the etching rate. In yet another embodiment, trenches for metal lines, as readily understood by those skilled in the art, may be etched simultaneously with the texturing of the surface, eliminating the need, cost and time for laser scribing, although laser scribing the trenches is still contemplated herein. It should be appreciated by one skilled in the art that any combination of the embodiments is contemplated herein.

The microstamp includes a regular or irregular array of shapes thereon including, but not limited to: polyhedra such as cubes, tetrahedrons, octahedrons, dodecahedron, icosahedron; prisms such as triangular prisms, cuboids, rectangular prisms, pentagonal prisms, hexagonal prisms, octagonal prisms; pyramids such as triangularly shaped pyramids, square shaped pyramids and pentagonal shaped pyramids; hemispherical; other spherical-based shapes; other pointy shapes such as cones; ellipsoidal-based shapes; and combinations thereof. The regular or irregular array can include any number of different shapes of various sizes having various levels of symmetry. Preferably, when the microstamp includes etchant holes, the microstamp comprises a hydrophilic surface to minimize surface tension issues at the etchant holes. It should be appreciated that the etchant holes may be any size so long as the integrity of the microstamp is not compromised. If necessary, the bath may be forced through smaller etchant holes using backside pressure.

Although not wishing to be bound by theory, there are several possible mechanisms of action when using a microstamp including, but not limited to: the etching rate of the substrate should be highest where the pressure is highest; the microstamp may break through any residual surface oxide and thus increase the etching rate; the pressure may induce amorphism in the substrate which can then act as an etch stop; and/or the microstamp may act as a removable “mask” limiting where the etching chemistry may attack the substrate. The mechanism will depend on the choice of specific chemistry used (e.g., acidic, basic, additives/surfactants, etc.), the time, the temperature and/or the pressure, etc.

Following the application of the microstamp to the substrate and the etching process, the substrate surface is preferably rinsed to remove the etchant as well as any reaction products. The stamp may be reused multiple times. In one embodiment, it may be advantageous to use multiple stamps to impart an increasingly rough texture to the substrate surface. The etching chemistry may be altered during each of these process steps to optimize photovoltaic cell performance. Additional process step(s), chemical additives, and/or process chemistries may be added to minimize the surface recombination velocity.

Advantageously, the method of the second aspect allows for a reproducible surface structure with optimized texture. The texture may be a variety of sizes from the micron-scale to the nanoscale to a mixture of sizes between the micron-scale and nanoscale.

In one embodiment of the method of the second aspect, the semiconductor material is microscale roughened using the composition and method of the first aspect, as described herein, and thereafter, nanoscale surface roughening is achieved using the method of the second aspect (i.e., the microstamp).

In another embodiment of the method of the second aspect, the semiconductor material is microscale roughened method of the second aspect (i.e., using a microscale microstamp), and thereafter nanoscale surface roughening is achieved using the method of the second aspect (i.e., using a nanoscale microstamp).

In still another embodiment of the method of the second aspect, the semiconductor material is microscale roughened method of the second aspect (i.e., using a microscale microstamp), and thereafter further microscale surface roughening is achieved using the method of the first aspect.

For single crystal silicon surfaces, either an anisotropic etch or an isotropic etch may be used with the microstamp. For polycrystalline silicon, it is expected that an isotropic etch will be most advantageous since multiple crystal planes are exposed. Examples of anisotropic etches include (i) a mixture of a base (e.g., NaOH and KOH) and optionally an alcohol (e.g., isopropanol); (ii) ethylenediamine and pyrocatechol with or without water; (iii) aqueous hydrazine; (iv) amine gallates (e.g., an alkanolamines with gallic acid, water, pyrazine, optionally oxidants and optionally surfactants); and (v) the etchant composition of the first aspect. The most commonly used wet isotropic etchant is a solution of nitric acid, hydrofluoric acid, and optionally acetic acid. Other etchants are known to those skilled in the art. This etching process occurs preferentially at defects, therefore, when saw damage is present, etching (and therefore texturing) occurs independent of the crystal orientation. As noted above, the microstamp may either enhance or inhibit the etching rate, thus imparting a specific surface texture. Advantageously, etching steps to minimize saw damage may not be required, thus simplifying the overall cell fabrication process.

Acidic isotropic etches result in lower reflection than traditional anisotropic etches on p-Si or mc-Si, and thus better cell conversion efficiency. After acidic texturing, wafers must be immersed in a dilute NaOH or KOH solution to remove a thin porous silicon layer that is formed during the texturing step. This is followed by a neutralization step to remove all Na or K′ ions from the surface before emitter diffusion. Although this wet texture process is effective at yielding higher conversion efficiencies, it is multi-step, chemically intensive, and tends to generate significant waste. This process may be simplified by using an oxidant along with an acid fluoride, instead of the immersion in the dilute NaOH or KOH solution, to oxidize the freshly etched silicon surface and avoid generating a porous silicon layer. Avoiding the caustic etchants (i.e., NaOH and KOH) eliminates the need for a neutralization step.

Alternatively, a viscous alkaline silicon etch paste may be squeezed between the microstamp and the silicon surface, e.g., as described in U.S. Patent Application Publication No. 2005/0247674 in the name of Kukelbeck et al. and entitled “Etching Pastes for Silicon Surfaces and Layers,” which is incorporated by reference herein in its entirety.

Oxidants contemplated for the isotropic or anisotropic etch include, but are not limited to, methanesulfonic acid (MSA), ozone, bubbled air, ethanesulfonic acid, benzenesulfonic acid, 2-hydroxyethanesulfonic acid, cyclohexylaminosulfonic acid, n-propanesulfonic acid, n-butanesulfonic acid, or n-octanesulfonic acid, hydrogen peroxide (H₂O₂), FeCl₃ (both hydrated and unhydrated), oxone (2 KHSO₅.KHSO₄.K₂SO₄), ammonium polyatomic salts (e.g., ammonium peroxomonosulfate, ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), ammonium persulfate ((NH₄)₂S₂O₈), ammonium hypochlorite (NH₄ClO)), sodium polyatomic salts (e.g., sodium persulfate (Na₂S₂O₈), sodium hypochlorite (NaClO)), potassium polyatomic salts (e.g., potassium iodate (KIO₃), potassium permanganate (KMnO₄), potassium persulfate, nitric acid (HNO₃), potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈)), tetrabutylammonium polyatomic salts (e.g., tetrabutylammonium peroxomonosulfate), peroxomonosulfuric acid, ferric nitrate (Fe(NO₃)₃), cerium ammonium nitrate (CAN), urea hydrogen peroxide ((CO(NH₂)₂)H₂O₂), peracetic acid (CH₃(CO)OOH), and combinations thereof.

Acid fluorides contemplated for the isotropic or anisotropic etch include, but are not limited to, hydrogen fluoride (HF); ammonium fluoride (NH₄F); tetraalkylammonium fluoride (NR₄F); alkyl hydrogen fluoride (NRH₃F); ammonium hydrogen bifluoride (NH₅F₂); dialkylammonium hydrogen fluoride (NR₂H₂F); trialkylammonium hydrogen fluoride (NR₃HF); trialkylammonium trihydrogen fluoride (NR₃:3HF); anhydrous hydrogen fluoride pyridine complex; anhydrous hydrogen fluoride triethylamine complex; amine hydrogen fluoride complexes; and combinations thereof, where R may be the same as or different from one another and is selected from the group consisting of straight-chained or branched C₁-C₆ alkyl groups (e.g., methyl, ethyl, propyl, butyl, pentyl, hexyl) and where the amine includes straight-chained or branched C₁-C₂₀ alkylamines, substituted or unsubstituted C₆-C₁₀ arylamines, glycolamines, alkanolamines, and amine-N-oxides including, but not limited to: pyridine; 2-ethylpyridine; 2-methoxypyridine and derivatives thereof such as 3-methoxypyridine; 2-picoline; pyridine derivatives; dimethylpyridine; piperidine; piperazine; triethylamine; triethanolamine; ethylamine, methylamine, isobutylamine, tert-butylamine, tributylamine, dipropylamine, dimethylamine, diglycol amine; monoethanolamine; pyrrole; isoxazole; 1,2,4-triazole; bipyridine; pyrimidine; pyrazine; pyridazine; quinoline; isoquinoline; indole; imidazole; N-methylmorpholine-N-oxide (NMMO); trimethylamine-N-oxide; triethylamine-N-oxide; pyridine-N-oxide; N-ethylmorpholine-N-oxide; N-methylpyrrolidine-N-oxide; N-ethylpyrrolidine-N-oxide; 1-methylimidazole; diisopropylamine; diisobutylamine; aniline; aniline derivatives; and combinations thereof.

Anionic, cationic, non-ionic and zwitterionic surface active agents may also be employed in the isotropic or anisotropic etches to minimize surface reflectance by controlling surface tension. For example, a textured surface may be represented by semi-spherical scallops where D and h denote the width and depth of the texture, respectively, and r is the radius of a sphere (see, e.g., FIG. 2). The width of the surface texture is determined primarily by the surface tension of the liquid while the texture depth is determined by the etching chemistry/rate/time. The relationship between D, h and r is:

D²=8rh−4h²

In other words, the reflectance depends on both h and D and a large value of h/D is necessary to obtain a low reflectance (see, e.g., Nishimoto, Y., et al., J. Electrochem. Soc., 146, 457-461 (1999). Measured results were in good agreement with this simulation. The surfactants contemplated for use were introduced hereinabove. In a preferred embodiment, the nonionic surfactant may be an ethoxylated fluorosurfactant such as ZONYL® FSO-100 fluorosurfactant (DuPont Canada Inc., Mississauga, Ontario, Canada).

In the method described herein, surfactants/defoaming agents may be added to the bath, wherein the surfactants/defoaming agents have different “bubble generation” (i.e., “foaming”) characteristics to tune the reflectance of the textured surface. The bubbles play a role similar to the microstamp in that they control where etching takes place. For example, Pluronic 25R2 (a non-ionic, non-fluorinated—PEG/PPG/PEG polymer) may be used for very small bubble generation while DDBSA (anionic—dodecylbenzene sulfonic acid, sodium salt) should lead to the formation of larger bubbles. Intermediate-sized bubbles should be formed from Dowfax 3B2 (anionic—alkyldiphenyloxide disulfonate sodium salt). These materials may be employed either individually or in combination with each other and the microstamping technique to yield multi-scale or fractal surfaces.

As introduced hereinabove, the microstamp may be made out of a conductive material (e.g., metal) or coated with a conductive material and an electrochemical process initiated between the stamp and the substrate. In one embodiment, the stamp need not touch the substrate. The bath may be either alkaline or acidic; additives such as surfactants and foaming agents may also be used. Alternatively, the stamp may be used as a contact etch mask thus limiting areas in which etching may take place. The etch rate may be enhanced using photons either through the stamp (using an optically transparent yet conductive material or a coating with these properties (e.g., indium tin oxide)) and/or through the silicon substrate. By controlling the potential and the solution chemistry, all crystallographic faces of silicon may be etched at comparable rates and similar shapes, thus leading to reproducible surface texturing even as the crystal structure varies (see, e.g., Gregory Zhang, Electrochemistry of Silicon and its Oxide, Kluwer Academic/Plenum Publishers, New York, 2001). Consistent with the teaching herein, trenches for metal contact lines may be etched simultaneously and/or laser scribing may be utilized. A deionized water rinse may be used to remove any residual acid or base. Advantageously, electrochemical etching is rapid thus increasing the throughput of cells through a solar fab.

In addition to wet chemical and electrochemical etching of silicon, a similar microstamp may be used in gas phase etching. For example, XeF₂ can be used as a plasma-less, isotropic, vapor-phase texturing etchant. XeF₂ etches silicon rapidly (˜2 μm/min) with a high selectivity over SiO₂, SiN, Al and photoresist (>1000:1), thus any of these materials may be used as a mask to protect the back-side of the wafer during the texturing process (if necessary). XeF₂ has not been listed as a greenhouse gas and thus could potentially eliminate the use of well known greenhouse gases from plasma/vapor phase texturing processes, as well as the surface damage caused by RIE plasma processes. This potentially eliminates any subsequent wet-chemical etching steps. Alternative gases for use in gas phase etching include, but are not limited to, F₂, HF and ClF₃. In another embodiment, a photoablative process can be used, wherein the substrate surface is covered with a discrete array of masking material, such as metal and/or particles, and thereafter an excimer laser is used to ablate the exposed silicon.

Note that the method of the second aspect is not limited to texturing of silicon photovoltaic cells and may be applied to not only other photovoltaic materials (e.g., GaAs, CdTe, CIGS, etc.), but to a wide variety of substrates in many fields including optics, controlled surface hydrophobicity/hydrophilicity, etc.

In a third aspect, a method of introducing a micron scale and a nanometer scale surface roughness to the surface of a photovoltaic cell substrate is described. More specifically, the method of the third aspect relates to the deposition of nanoparticles or the introduction of metal induced pitting to a micron scale roughened substrate surface.

Furthermore, all the wet-based formulations proposed here can be applied to other wet-processes in the solar cell production, such as Saw Damage Removal (SDR), Phosphorous Silicate Glass (PSG) removal, Edge Isolation and SiₓN_{y} removal.

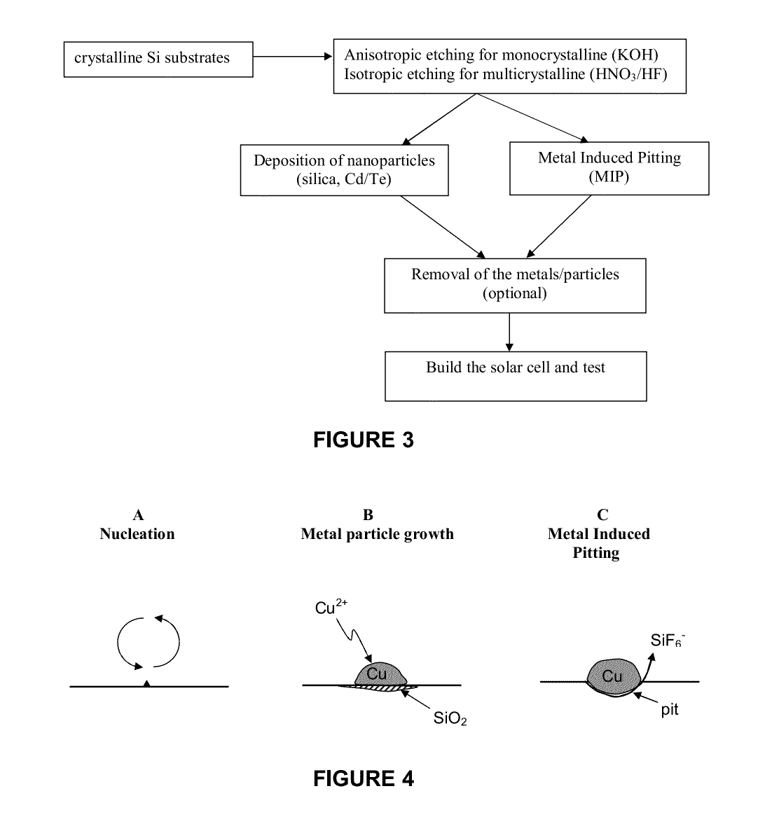

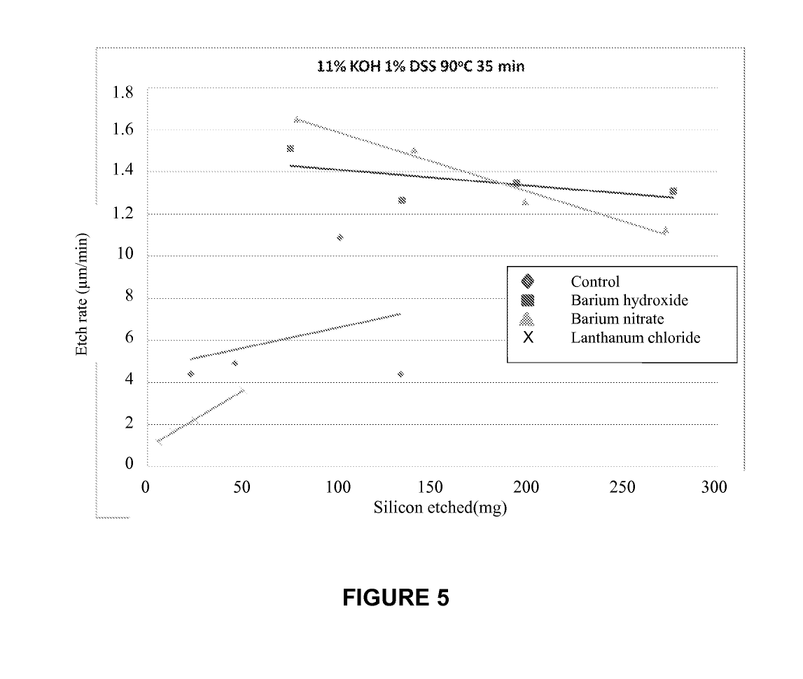

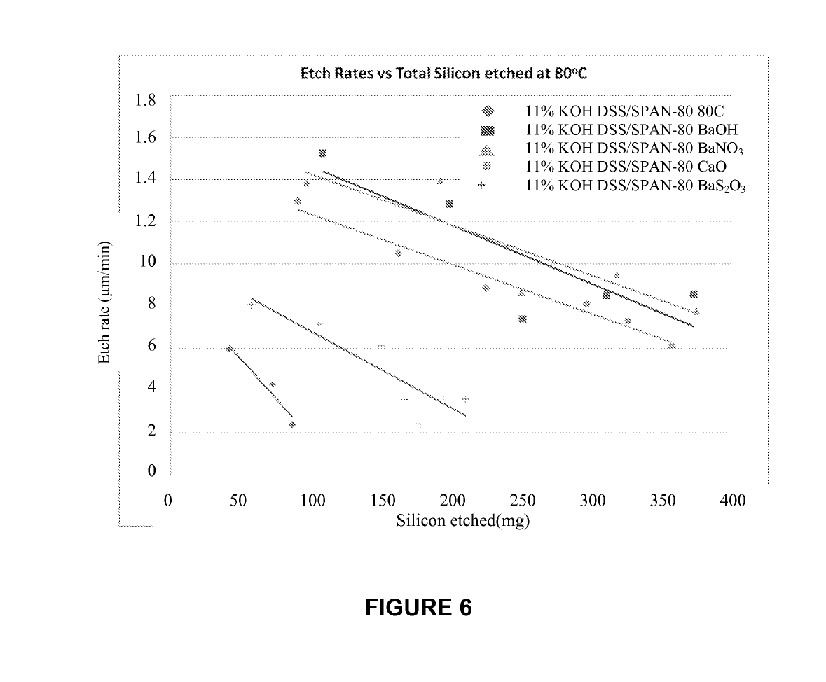

The method of introducing texture to the substrate is illustrated in FIG. 3, wherein a silicon-containing substrate (e.g., monocrystalline or polycrystalline/multicrystalline) is etched to form a micron-scale roughened substrate surface. The method of etching depends on the nature of the silicon-containing substrate, wherein KOH/NaOH and optionally isopropanol is conventionally used to anisotropically etch a monocrystalline Si substrate while a mixture of nitric acid and HF and optionally acetic acid is conventionally used to isotropically etch a multicrystalline Si substrate. Other etchants include carbonate, bicarbonate, or hydrazine and optionally at least one alcohol or at least one surfactant. Alternatively, the micron-scale roughness is introduced using the composition and method of the first aspect, as described herein. The substrate having the micron-scale texture then undergoes nanoscale texturing, wherein (i) nanoparticles are deposited thereon; or (ii) metal induced pitting (MIP) is initiated. The metals or nanoparticles may be optionally removed. The textured substrate can be subsequently used to build a solar cell. In an alternative embodiment, the micron-scale textured substrate of the second aspect is subjected to nanoscale texturing wherein (i) nanoparticles are deposited thereon; or (ii) metal induced pitting (MIP) is initiated. The metals or nanoparticles may be optionally removed. The textured substrate of the alternative embodiment can be subsequently used to build a solar cell.

The nanoparticles, specifically silica, CdTe nanoparticles, CdSe nanoparticles or other chalcogenides, can be deposited in situ or ex situ using solution-based or gas phase deposition methods, as readily understood by one skilled in the art. In another embodiment, a ceramic or metal doped ceramic nanoparticle such as TiO₂ can be deposited for a photoassist process, wherein UV light can activate etching in the vicinity of the particle.

One potential advantage of introducing these nanoparticles, which could bear variously tunable charges and morphology, is to enable an effective field induced surface passivation which ultimately leads to the reduction of SRV.

Metal induced pitting involves the immersion of the micron-scale textured substrate in a solution including a metal salt and a silicon oxide based etchant such as an acid fluoride or KOH. The metal salt can include copper (II), gold (I), silver (I), Pt(II), Pd (II), and combinations thereof. MIP results in the formation of craters on the surface of the micron-scale textured surface, hence introducing a secondary structure. Although not wishing to be bound by theory, the inventors speculate that p-type doped silicon is more prone to MIP than n-type doped silicon. An example of metal induced pitting is shown in FIG. 4 wherein nucleation at the silicon surface leads to the formation of a metal particle (based on the metal salt used) and the formation of silicon oxide in the silicon proximate to the metal particle. Thereafter, a fluoride salt may be introduced wherein the silicon oxide dissolves and the metal particle is released/oxidized, leaving behind a pit.

Advantageously, the method of the third aspect is a simple two-step process that requires only inexpensive, commodity chemicals.

In a fourth aspect, remote plasma source (RPS) or reactive ion etching (RIE), i.e., dry etching processes, is used to etch micron-scale and nanoscale features into the silicon-containing substrate, preferably without the necessity of introducing the silicon-containing substrate to an anisotropic etch bath (i.e., KOH/isopropanol) or the isotropic etch bath (i.e., HNO₃/HF/CH₃COOH). In other words, the RPS or RIE etching can be a one-step texturing process and the resulting textured substrate can be subsequently used to build the solar cell. In another embodiment, the RPS or RIE etching may be a two step process wherein the first etch introduces a primary roughness while the second etch introduces a secondary roughness. The first etch can be a wet or dry etch while the second etch is a dry etch. For example, the primary roughness may be a micron-scale texture introduced using the composition and method of the first aspect while the secondary roughness may correspond to nanoscale roughness. It should be appreciated that the technique used in the first step can be the same as or different from the technique used in the second step. In another embodiment, the textured substrate of the second aspect is subjected to a RPS or RIE etch to introduce nanoscale features according to the fourth aspect and the resulting textured substrate can be subsequently used to build the solar cell.

Advantageously, the method of the fourth aspect is a one-sided process and does not require the presence of a defect for isotropic etching.

In a fifth aspect, another method of introducing a micron scale and a nanometer scale surface roughness to the surface of a photovoltaic cell substrate is described. More specifically, the method of the fifth aspect relates to the deposition of nanoparticles on a micron scale roughened substrate surface.

The method of introducing texture to the substrate according to the fifth aspect includes the etching of a silicon-containing substrate (e.g., monocrystalline or polycrystalline/multicrystalline) to form a micron-scale roughened substrate surface. The method of etching depends on the nature of the silicon-containing substrate, wherein KOH and optionally isopropanol is conventionally used to anisotropically etch a monocrystalline Si substrate while a mixture of nitric acid and HF and optionally acetic acid is conventionally used to isotropically etch a multicrystalline Si substrate. Alternatively, the micron-scale texture is obtained using the composition and method of the first aspect described herein, according to the second aspect described herein, or using the RPS or RIE etch of the fourth aspect described herein. Metal nanoparticles are then deposited on the substrate having the micron-scale texture, wherein (i) noble metal nanoparticles are deposited thereon using spin-on coating instead of gas phase deposition; or (ii) non-noble metal nanoparticles are deposited using solution-based deposition processes or gas phase deposition. Nanoscale roughness is achieved using metal-induced catalysis using a HF/H₂O₂ or an alternative composition in the presence of the deposited metal or some other metal catalyst present in the HF/H₂O₂ or alternative composition. In another embodiment, the catalysis may be photoinduced, as readily understood by one skilled in the art. After the nanoscale roughness is imparted in the substrate surface, the metal nanoparticles can be removed to yield the textured substrate, which can be subsequently used to build a solar cell. For the purposes of this disclosure, the “alternative composition” may be any solution disclosed in International Patent Application No. PCT/US06/60696 filed Nov. 9, 2006 entitled “Composition and Method for Recycling Semiconductor Wafers Having Low-k Dielectric Materials Thereon,” International Patent Application No. PCT/US08/58878 filed Mar. 31, 2008 entitled “Methods for Stripping Material for Wafer Reclamation,” International Patent Application No. PCT/US08/66906 filed Jun. 13, 2008 entitled “Wafer Reclamation Compositions and Methods,” and International Patent Application No. PCT/US09/59199 filed Oct. 1, 2009 entitled “Use of Surfactant/Defoamer Mixtures for Enhances Metals Loading and Surface Passivation of Silicon Substrates,” which are all hereby incorporated by reference herein in their entireties. In all cases, the surface structure and surface/interface chemistry must be such that the surface recombination velocity is not substantially increased.

Losses in solar cell efficiency come primarily from four areas—reflectance losses which can be addressed by a texturing process, thermodynamic efficiency which is a result of the semiconductor band gap, resistive electrical losses which arise from the material and interface properties, and recombination losses. Recombination loss occurs when the photo-generated electron-hole pairs combine with other carriers before they can migrate and be collected at the cell's p-n junction. A portion of minority carriers tend to migrate towards the surface so by manipulating the surface potential, the minority carriers can be repulsed or attracted which directly affects the rate of recombination at the surface of the semiconductor. Approaches to modifying the surface potential include chemical modification of the surface, adsorption of a thin film, or coating with a thin film material compatible with the design of the cell. Thus two sources of loss, reflection and recombination, could potentially be addressed with a single chemical process. Although not wanting to be bound by theory, if the top layer is a p-type semiconductor then the majority carrier will be holes. If a dipole at the surface is achieved, carriers from the surface may be repelled or attracted. For example, changing Si—OH at the surface to Si—H results in a surface where the holes are not as attracted and the rate of surface recombination decreases. With regards to an n-type semiconductor, halogen termination or aminosilanes may slow down surface recombination.

The features and advantages are more fully shown by the illustrative examples discussed below.

### Example 1

To demonstrate the efficacy of the compositions of the first aspect for the etching of silicon, formulations were prepared and silicon coupons were immersed in said formulations and the etch rate determined.

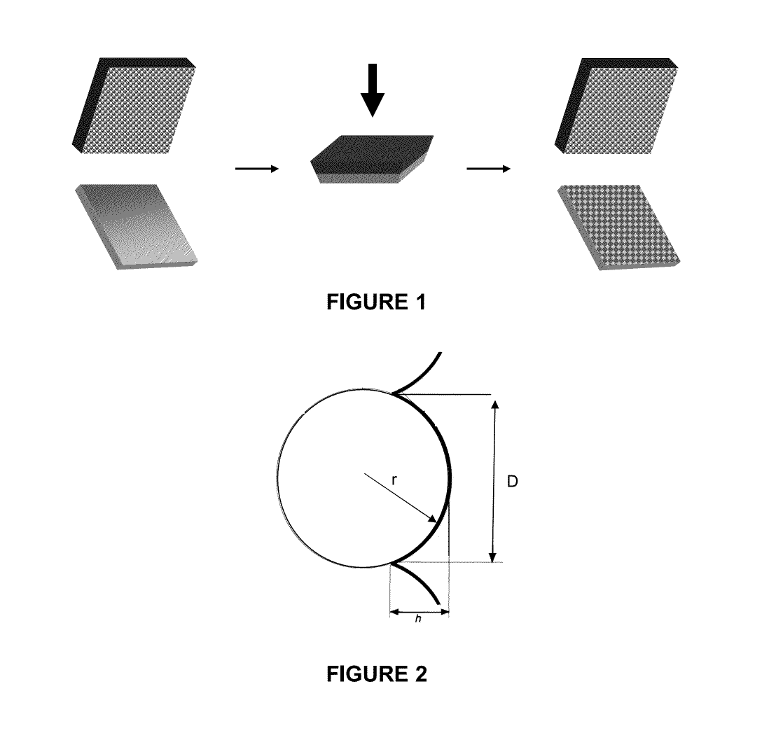

In a first example, a formulation including 11 wt % KOH, 1 wt % DSS, 0.01 wt % metal salt, and water were prepared, wherein the metal salts included Ba(OH)₂, Ba(NO₃)₂, and lanthanum chloride. A control was prepared that had no metal salt. The silicon coupon was immersed in each formulation for 35 minutes at 90° C. The results of the silicon etch are shown in FIG. 1, wherein it can be seen that the presence of barium salts in the composition increased the etch rate of the silicon surface. Although not wishing to be bound by theory, it is surmised that the decrease in etch rate over time is a function of increasing silicate concentration in the bath and/or a decrease in KOH concentration over time.

Although barium salts are useful additives with regards to the etch rate of silicon, there are some disadvantages including the disposal of barium and the expense. Accordingly, compositions were prepared that included CaO, as well as a two surfactant system. A formulation including 11 wt % KOH, 0.01-0.03 wt % DSS, 0.005-0.015 wt % Span 80, 0.01 wt % metal salt, and water, wherein the metal salts included Ba(OH)₂, Ba(NO₃)₂, CaO and BaS₂O₃. A control was prepared that had no metal salt. The silicon coupon was immersed in each formulation for 10-20 minutes at 80° C. The results of the silicon etch are shown in FIG. 2. There are two things to note when comparing FIGS. 1 and 2. Firstly, the etch rate of silicon with the CaO is similar to that of the barium salts. Secondly, by introducing a second surfactant, the etch rate of silicon at 80° C. (FIG. 2) is approximately equal to the etch rate of silicon using the one surfactant composition at 95° C.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

What is claimed is:

1. A method of introducing a surface roughness to a substrate surface, said method comprising immersing a microstamp and a substrate in a bath comprising an etchant composition and pressing the microstamp to the substrate to etch micrometer scale features into the substrate surface.

2. The method of claim 1, wherein the microstamp is a mirror inverse of an optimum surface structure of the substrate.

3. The method of claim 1, wherein the microstamp comprises at least one hole wherein the at least one hole facilitates that the etching composition reaches the substrate surface and wherein the at least one hole facilitates removal of the etch products.

4. The method of any of the preceding claims, wherein a potential is placed on the microstamp and the substrate to enhance the etching rate.

5. The method of claim 1, wherein the microstamp includes a regular or irregular array of shapes, wherein the shapes include at least one shape selected from the group consisting of cubes, tetrahedrons, octahedrons, dodecahedron, icosahedron, triangular prisms, cuboids, rectangular prisms, pentagonal prisms, hexagonal prisms, octagonal prisms, triangularly shaped pyramids, square shaped pyramids, pentagonal shaped pyramids, hemispherical shapes, other spherical-based shapes, cones, ellipsoidal-based shapes, and combination thereof.

6. The method of claim 1, wherein the substrate is rinsed to remove the etchant composition and any reaction products.

7. The method of claim 1, wherein the etchant composition etches the substrate anisotropically or isotropically.

8. The method of claim 1, wherein the etchant composition comprises at least one alkaline component, at least one surfactant, at least one metal salt, and water, wherein the etchant composition is substantially devoid of any low boiling point alcohol components.

9. The method of claim 8, wherein the alcohol components comprise any straight-chained or branced C₁-C₆ alcohols.

10. The method of claim 8, wherein the at least one alkaline component comprises NaOH, KOH, RbOH, CsOH, Na₂CO₃, NaHCO₃, K₂CO₃, KHCO₃, NR₄OH, or any combination thereof, wherein R can be the same as or different from one another and is selected from the group consisting of C₁-C₆ alkyls, C₆-C₁₀ aryl, and combinations thereof.

11. The method of claim 8, wherein the at least one alkaline component comprises NaOH, KOH, or a combination of NaOH/KOH.

12. The method of claim 8, wherein the at least one metal salt comprises a Group II metal, a Group IV metal, copper, lanthanum, or combinations thereof.

13. The method of claim 8, wherein the at least one metal salt comprises Ca(OH)₂, Sr(OH)₂, Ba(OH)₂, CaO, SrO, BaO, Ca(NO₃)₂, Sr(NO₃)₂, Ba(NO₃)₂, Ca(CO₃)₂, CuSO₄.5H₂O, CaSO₄, SrSO₄, BaSO₄, Cu(OH)₂, Na₂(GeO₃), Na₂(SnO₃), Na₄(SiO₄), K₂(GeO₃), K₄(SiO₄), K₂(SnO₃), LaCl₃.7H₂O, La₂(SO₄)₃ and its hydrates, SnCl₄.5H₂O, and combinations thereof.

14. The method of claim 8, wherein the at least one metal salt comprises CaO, CaOH, CaSO₄, or BaOH.

15. The method of claim 8, wherein the at least one surfactant comprises a species selected from the group consisting of fluoroalkyl surfactants, ethoxylated fluorosurfactants, polyethylene glycols, polypropylene glycols, polyethylene glycol ethers, polypropylene glycol ethers, dodecylbenzenesulfonic acid, polyacrylate polymers, dinonylphenyl polyoxyethylene, silicone polymers, modified silicone polymers, acetylenic diols, modified acetylenic diols, alkylphenol polyglycidol ether, sorbitan monolaurate, sorbitan monopalmitate, sorbitan monostearate, sorbitan tristearate, sorbitan monooleate, sorbitan trioleate, polyoxyethylene (20) sorbitan monolaurate, polyoxyethylene (20) sorbitan monopalmitate, polyoxyethylene (20) sorbitan monostearate, polyoxyethylene (20) sorbitan monooleate, polyoxyethylene sorbitan trioleate, polyoxyethylene sorbitan tristearate, alkyl polyglucosides, fluorosurfactants, sodium alkyl sulfates, ammonium alkyl sulfates, alkyl (C₁₀-C₁₈) carboxylic acid ammonium salts, sodium sulfosuccinates and esters thereof, alkyl (C₁₀-C₁₈) sulfonic acid sodium salts, di-anionic sulfonates, cetyltrimethylammonium bromide (CTAB), cetyltrimethylammonium hydrogen sulfate, ammonium carboxylates, ammonium sulfates, dimethyldodecylamine oxide (DMAO)), N-dodecyl-N,N-dimethylbetaine, betaine, sulfobetaine, alkylammoniopropyl sulfate, polyethylene glycol (PEG), polyethylene oxide (PEO), polypropylene glycol (PPG), polyvinyl pyrrolidone (PVP), hydroxyethylcellulose (HEC), acrylamide polymers, poly(acrylic acid), carboxymethylcellulose (CMC), sodium carboxymethylcellulose (Na CMC), hydroxypropylmethylcellulose, polyvinylpyrrolidone K30, BIOCARE™ polymers, DOW™ latex powders (DLP), ETHOCEL™ ethylcellulose polymers, KYTAMERT™ PC polymers, METHOCELT™ cellulose ethers, POLYOX™ water soluble resins, SoftCATT™ polymers, UCARE™ polymers, UCON™ fluids, PPG-PEG-PPG block copolymers, PEG-PPG-PEG block copolymers, and combinations thereof.

16. The method of claim 8, wherein the pH of the etchant composition is greater than 12.

17. The method of claim 1, further comprising silicon material.
